(19) United States
(12) Patent Application Publication
(10) Pub. No.: US 2025/0223154 A1
(43) Pub. Date: Jul. 10, 2025

(54) MICROELECTROMECHANICAL SYSTEM

(71) Applicant: AAC Technologies Pte. Ltd., Singapore (SG)

(72) Inventors: Scott Lyall Cargill, EB (GB); Yannick Pierre Kervran, HK (FR); Anup Patel, EB (GB); Euan James Boyd, EB (GB)

(21) Appl. No.: 18/404,834

(22) Filed: Jan. 4, 2024

(51) Int. Cl. B81B 7/00

(52) U.S. Cl. CPC B81B 7/0058; B81B 2201/0257; B81B 2203/0127; B81B 2203/0315; B81B 2203/04; B81B 2207/03

(57) ABSTRACT

A microelectromechanical system includes counter electrodes, a first diaphragm and a second diaphragm. The first diaphragm is provided with multiple first corrugations, each first corrugation includes a first crest and a first trough, and the first crests and troughs are arranged alternately in a third direction. The second diaphragm is provided with multiple second corrugations, each second corrugation includes a second crest and a second trough, and the second crests and troughs are arranged alternately in the third direction. The first crests are respectively aligned with the second troughs to form cavities, and the counter electrodes are disposed in the cavities respectively. The first troughs are respectively aligned with the second crests, and at least some of the first troughs are configured to be in direct contact with corresponding second crests. The system has an improved robustness while the high acoustic compliance and sensitivity from the sealed dual-diaphragm are maintained.

### TECHNICAL FIELD

The present disclosure relates to the field of electro-acoustic conversion devices, and in particular, to a microelectromechanical system and an electro-acoustic conversion device including the microelectromechanical system.

### BACKGROUND

Some microelectromechanical system (MEMS) consist of two corrugated diaphragms, counter electrodes and pillars. The two corrugated diaphragms are respectively located at opposite sides of the counter electrodes, where the troughs of one corrugated diaphragm are connected to the crests of the other corrugated diaphragm by the use of spacers to form a sealed cavity where the counter electrodes are placed in-between the crests of the corrugated diaphragm and the troughs of the other corrugated diaphragm respectively. The pressure inside the sealed cavity formed may be at a pressure different from the surrounding atmosphere outside the cavity.

However, if such structure is subjected to high displacements, for example resulting from powerful air blows or mechanical shocks, high stresses may appear in specific locations of the diaphragms, precisely and mostly in the diaphragm corners around the first or the two first pillars. This is a result of the two diaphragms attached to each other using stiff pillars that allow a limited amount of deformations of each diaphragm individually.

Therefore, it is desired to provide an improved microelectromechanical system which can overcome at least one of the above problems.

### SUMMARY

To address the above problems, in one aspect, the present disclosure provides a microelectromechanical system including:
a plurality of counter electrodes, arranged in a first direction;
a first diaphragm and a second diaphragm respectively disposed at opposite sides of the plurality of counter electrodes along a second direction and hermetically connected;
the first diaphragm being provided with a plurality of first corrugations, each of the plurality of first corrugations including a first crest and a first trough, and a plurality of first crests and a plurality of first troughs being arranged alternately in a third direction,
the second diaphragm being provided with a plurality of second corrugations, each of the plurality of second corrugations including a second crest and a second trough, and a plurality of second crests and a plurality of second troughs being arranged alternately in the third direction;
the plurality of first crests are respectively aligned with the plurality of second troughs to form cavities, and the plurality of counter electrodes are received in the cavities respectively; and
the plurality of first troughs are respectively aligned with the plurality of second crests, and at least some of the plurality of first troughs are configured to be in direct contact each other with corresponding second crests.

In some embodiments, the cavities are hermetically sealed, with an inside pressure less than an external atmosphere.

In some embodiments, the cavities are under vacuum.

In some embodiments, first troughs at outermost and 2^{nd} outermost rings of the first diaphragm are configured to be in direct contact each other with corresponding second crests at outermost and 2^{nd} outermost rings of the second diaphragm.

In some embodiments, bottoms of the first troughs and tops of the second crests are configured to be in a form of planes.

In some embodiments, a length of a region that a first trough and a corresponding second crest contacting with each other in the third direction is equal to or less than a length of the planes of the first trough and the corresponding second crest.

In some embodiments, the first diaphragm further includes one or more bumps, the bumps being disposed at the bottoms of the first troughs and configured to be in contact with the tops of the second crests. In some embodiments, a length of the bumps in the third direction is equal to or less than the length of the planes. In some embodiments, the bumps form a circular shape/contact or are in a form of a line.

In some embodiments, the second diaphragm further includes one or more bumps, and the bumps being disposed at the tops of the second crests and configured to be in contact with the bottoms of the first troughs. In some embodiments, a length of the bumps in the third direction is equal to or less than the length of the planes. In some embodiments, the bumps are anti-stiction bumps or in a form of a line.

In some embodiments, the first diaphragm further includes one or more dimples, the dimples being provided at the bottoms of the first troughs and configured to contact the tops of the second crests.

In some embodiments, the second diaphragm further includes one or more dimples, the dimples being provided on the tops of the second crests, and regions of the second crests except the dimples being configured to contact the bottoms of the first troughs.

In some embodiments, the bottoms of the first troughs are configured to be offset a first distance from tops of corresponding second crests in the third direction. In some embodiments, the first distance is less than the length of the planes.

In some embodiments, the third direction is a radial or transverse direction.

In some embodiments, tops of the first crests or bottoms of the second troughs are configured to be in a form of dome shapes.

In some embodiments, at least one bottom of the first crests or at least one top of the second troughs is configured to be in the form of the dome shapes.

The present disclosure has following advantages in comparison with existing technologies.

By removing the spacers between the first diaphragm and the second diaphragm such that at least some of the first troughs are configured to contact each other with the corresponding second crests, the two corrugations of the present disclosure thereby can be effectively, at rest and under normal operation, in contact or bonded at their respective bottoms due to a high pressure gradient forcing the two corrugations to move towards the counter electrodes direction/or towards the middle plane of the system, assuming an equivalent atmospheric pressure on both side of the structure. When the system is subjected to high displacements, each corrugation where the spacer was removed can move freely in a vertical direction and slide in a horizontal direction allowing a decrease of the maximum stress of the device by up to 50%

Therefore, the microelectromechanical system of the present disclosure has an improved robustness while the high acoustic compliance and sensitivity from the sealed dual-diaphragm are maintained.

In another aspect, the present disclosure provides an electro-acoustic conversion device including the microelectromechanical system described above, and a driver circuit electrically connected to the microelectromechanical system.

The electro-acoustic conversion device has the same advantages in comparison with the existing technologies as the microelectromechanical system described above and will not be described herein.

### BRIEF DESCRIPTION OF DRAWINGS

In order to explain technical solutions of embodiments of the present disclosure more clearly, accompanying drawings used to describe the embodiments are briefly introduced below. It is evident that the drawings in following description are only concerned with some embodiments of the present disclosure. For those skilled in the art, in a case where no inventive effort is made, other drawings may be obtained based on these drawings.

FIG. 1 illustrates a microelectromechanical system in accordance with some exemplary embodiments of the present disclosure.

FIG. 2 is a cross-sectional view of a portion of the microelectromechanical system of FIG. 1.

FIG. 3 is a cross-sectional view of a portion of the microelectromechanical system in accordance with some other exemplary embodiments of the present disclosure.

FIG. 4 is a cross-sectional view of a portion of the microelectromechanical system in accordance with some other exemplary embodiments of the present disclosure.

FIG. 5 is a cross-sectional view of a portion of the microelectromechanical system in accordance with some other exemplary embodiments of the present disclosure.

FIG. 6 is a cross-sectional view of a portion of the microelectromechanical system in accordance with some other exemplary embodiments of the present disclosure.

FIG. 7 is a schematic diagram of an electro-acoustic conversion device in accordance with some other exemplary embodiments of the present disclosure.

Description of the drawings reference numbers are as follows. Herein the drawing reference numbers shall not be constructed as limiting the claims. 1, counter electrode; 2, first diaphragm; 21, first corrugation; 211, first crest; 212, first trough; 22, spoke; 3, second diaphragm; 31, second corrugation; 311, second crest; 312, second trough; 4, cavity; 5, plane; 6, bump; 7, dimple; 8, spacer.

### DETAILED DESCRIPTION OF THE EMBODIMENTS

The present disclosure will be further illustrated with reference to the accompanying drawings. It shall be noted that the elements of similar structures or functions are represented by like reference numerals throughout the figures. The embodiments described herein are not intended as an exhaustive illustration or description of various other embodiments or as a limitation on the scope of the claims or the scope of some other embodiments that are apparent to one of ordinary skills in the art in view of the embodiments described in the present disclosure. In addition, an illustrated embodiment need not have all the aspects or advantages shown.

In the description of the present disclosure, it is to be understood that the terms “first” or “second” etc. are used primarily to distinguish between different devices, elements or components (which may or may not be of the same specific type and construction) and are not intended to indicate or imply a relative importance and number of the devices, elements or components indicated. The term “plurality” means two or more.

The terminology used in the description of the various described embodiments herein is for the purpose of describing particular embodiments only and is not intended to be limiting. As used in the description of the various described embodiments and the appended claims, the singular forms “a”, “an” and “the” are intended to include the plural forms as well, unless the context clearly indicates otherwise. It should also be understood that the term “and/or” as used herein refers to and encompasses any and all possible combinations of one or more of the associated listed items. It should be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

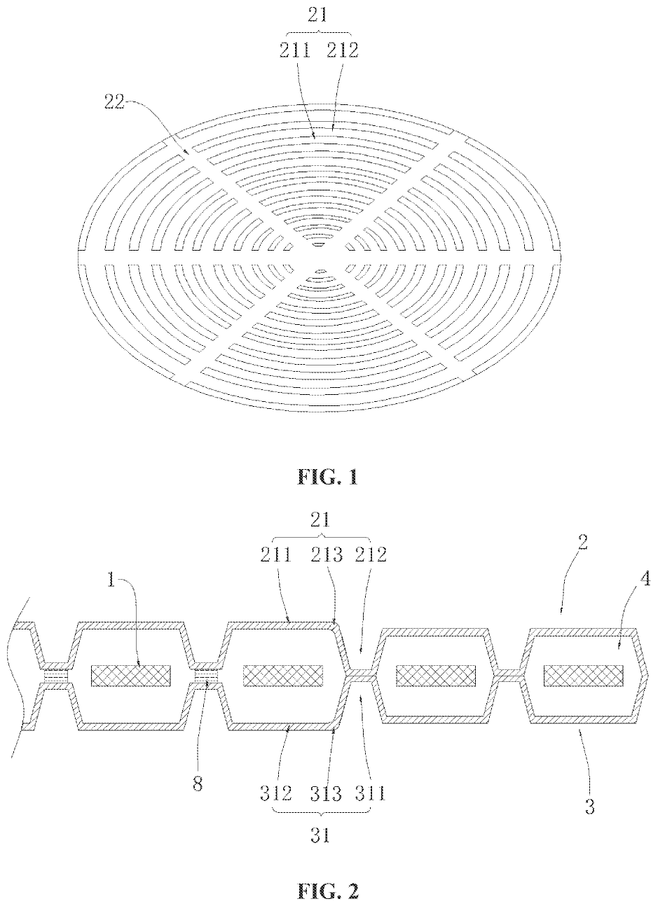

Referring to FIG. 1 and FIG. 2, it illustrates a microelectromechanical system according to some exemplary embodiments of the present disclosure. The microelectromechanical system includes a plurality of counter electrodes 1 arranged along a first direction, a first diaphragm 2 and a second diaphragm 3 respectively disposed at opposite sides of the counter electrodes along a second direction and hermetically connected. Herein the plurality of counter electrodes 1 are spaced along a third direction, and a spacer 8 may be provided between adjacent counter electrodes 1. One end of the spacer 8 along the second direction is connected to the first diaphragm 2, and the other end of the spacer 8 along the second direction is connected to the second diaphragm 3. Herein, the first direction is expressed as a circumferential direction, the second direction is expressed as a vertical or thickness direction, and the third direction is expressed as a radial direction.

Referring to FIG. 1 to FIG. 6, in some embodiments, the first diaphragm 2 and the second diaphragm 3 are corrugated conductive diaphragms, the first corrugated conductive diaphragm 2 is provided with a plurality of first corrugations 21, the second corrugated conductive diaphragm 3 is provided with a plurality of second corrugations 31, and the plurality of first corrugations 21 and the plurality of second corrugations 31 are arranged in the same direction. Each of the plurality of first corrugations 21 includes a first crest 211 and a first trough 212, i.e. a plurality of first crests and a plurality of first troughs are arranged alternately in the third direction. Similarly, each of the plurality of second corrugations 31 includes a second crest 311 and a second trough 322, i.e. a plurality of second crests and a plurality of second troughs are arranged alternately in the third direction. In the illustrated drawings of the present disclosure, the outermost end of the first corrugations 21 is a first crest 211, and the outermost end of the second corrugations 31 is a second trough 312 accordingly. Of course, in other embodiments, the outermost end of the first corrugations 21 may also be a first trough 212, and the outermost end of the second corrugations 31 may be a second crest 311 accordingly. It should be noted that the right edge in FIG. 2 to FIG. 6 is the edge of the microelectromechanical system.

The first crests 211 and the second troughs 312 are respectively aligned in the second direction and formed cavities 4 in which the counter electrodes 1 are received respectively. The cavities 4 are hermetically sealed, with an inside pressure less than an external atmosphere. In an example, the cavities 4 are under vacuum.

At least some or all of the first troughs 212 are respectively aligned with a corresponding number of the second crests 311 and are in a direct contact with each other without spacers, and the remaining of the first troughs 212 and the second crests 311 are connected to each other by spacers 8.

The first corrugated diaphragm 2 and the second corrugated conductive diaphragm 3 may be made of electrically conductive materials or include an insulating membrane with electrically conductive elements provided thereon. For example, the first corrugated diaphragm 2 and the second corrugated conductive diaphragm 3 include a Silicon Nitride membrane with Polysilicon electrodes formed on the surface of the diaphragms facing the counter electrodes 1 or on the surface of the diaphragms facing away from the counter electrodes 1 for providing conduction.

In some embodiments, the spacers 8 may be integrally formed with the first corrugated diaphragm 2 or the second corrugated conductive diaphragm 3. Alternatively, the spacers 8 may be integrally formed with the counter electrodes 1 and then slots are formed to separate the spacers 8 from the counter electrodes 1. In some embodiments, the spacers 8 may be independently formed from the first corrugated diaphragm 2 and the second corrugated conductive diaphragm 3. Alternatively, the spacers 8 may be independently formed from the counter electrodes 1 and then slots are formed to separate the spacers 8 from the counter electrodes 1. In an example, after the first corrugated diaphragm 2 and the second corrugated conductive diaphragm 3 are assembled together, the spacers 8 are provided between the first troughs 212 and the second crests 311.

Preferably, the counter electrodes 1 and the spacers 8 are arc-shaped and arranged in concentric arcs which span less than 360 degrees. The first crests 211 and troughs 212, the second crests 311 and troughs 312 are arc-shaped and arranged in concentric arcs which span less than 360 degrees. In an example, the first corrugated diaphragm 2 and the second corrugated conductive diaphragm 3 are circular. Spokes 22 are very narrow and each slot, first crest 211, first trough 212, second crest 311 and second trough 312 spans substantially 60 degrees. That is, the first corrugated diaphragm 2 is divided equally into six sections in the circumferential direction thereof. Each section includes a group of first crests 211 and first troughs 212 arranged alternately in a radial direction of the first corrugated conductive diaphragm 2. Adjacent sections are connected with each other via a spoke 22 which extends along the radial direction of the first corrugated conductive diaphragm 2.

Preferably, the first troughs 212 are evenly arranged in the radial direction of the first corrugated conductive diaphragm 2.

Accordingly, the second corrugated conductive diaphragm 3 is divided equally into six sections in the circumferential direction thereof. Each section includes a group of second crests 211 and second troughs 312 arranged alternately in a radial direction of the second corrugated conductive diaphragm 3. Adjacent sections are connected with each other via a spoke 22 which extends along the radial direction of the second corrugated conductive diaphragm 3.

Preferably, the second troughs 312 are evenly arranged in the radial direction of the second corrugated conductive diaphragm 3.

The counter electrodes 1 and the spacers 8 are also divided equally into six sections in the circumferential direction. Each section includes a group of concentric arc-shaped counter electrodes 1 and spacers 8 arranged in the radial direction. Adjacent sections are connected with each other via the spoke 22 which extends along the radial direction of the first corrugated conductive diaphragm 2. Opposite ends of the arc-shaped counter electrodes 1 are respectively connected with corresponding spokes such that the counter electrodes 1 are respectively suspended between adjacent spokes. The spacers 8 are disconnected from the counter electrodes 1 and the spokes by the slots.

Alternatively, the counter electrodes 1, the spacers 8, the first corrugated conductive diaphragm 2 and the second corrugated conductive diaphragm 3 may be divided into other number of sections, for example four sections or eight sections and so on. The sections may be evenly or unevenly arranged in the radial direction of the microelectromechanical system. In some other embodiments, the spacers 8, the first corrugated conductive diaphragm 2 and the second corrugated conductive diaphragm 3 may have other shapes, such as square, hexagonal, octagonal and so on.

Referring to FIG. 2 to FIG. 6, when only removing the spacers at the outermost and 2^{nd} outermost rings of the first corrugated conductive diaphragm 2 and the second corrugated conductive diaphragm 3, thus the first troughs 212 and the second crests 312 at the outermost and 2^{nd} outermost rings are in direct contact with each other. That is, the two first troughs 212 adjacent to the outermost edge of the first corrugated conductive diaphragm 2 are configured to in the second direction be in direct contact with each other with the corresponding two second crests 311. Since originally the stress at high displacement is maximal in the diaphragm corners around the outermost or two outermost spacers, such design allows more bending freedom for the corresponding troughs 212 and crests 311 and the stress is released.

It should be noted that the first diaphragm 2 may be provided with a first crest with a rounded corner 213, which is closest to the first trough without spacer, and/or the second diaphragm 3 may be provided with a second trough with a rounded corner 313, which is closest to at the second crest without spacer. Thus, the stress is further released.

When the bottoms of the first troughs 212 and/or the tops of the second crests 311 are in a form of a plane 5 as shown in FIG. 2, it is possible that the first troughs 212 and the second crests 311 stick to each other without being able to be separated at high structure displacements. To prevent this phenomenon to happen, various solutions for reducing contact area between a first trough and a corresponding second crest, may be provided as follows.

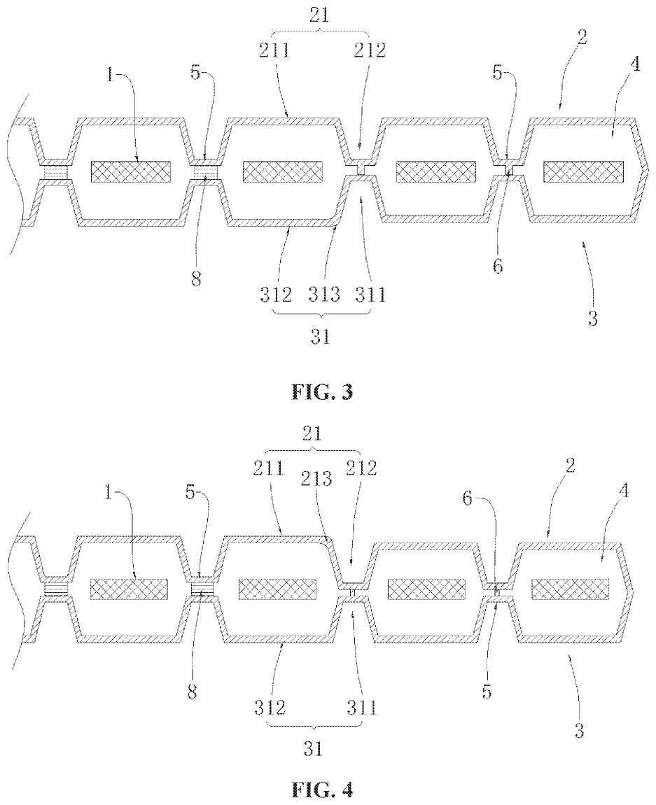

Referring to FIG. 3 to FIG. 5, by providing an anti-stiction structure/shape, such as a bump or a dimple, to reduce the contact area between the bottoms/tops of the corrugated conductive diaphragms, it is possible to prevent the first troughs 212 and the second crests 311 from sticking to each other without being able to be separated at high structure displacements. That is, in the second direction, a length of a region that each first trough 212 and each second crest 311 in contact with each other is equal to or less than a length of the plane 5.

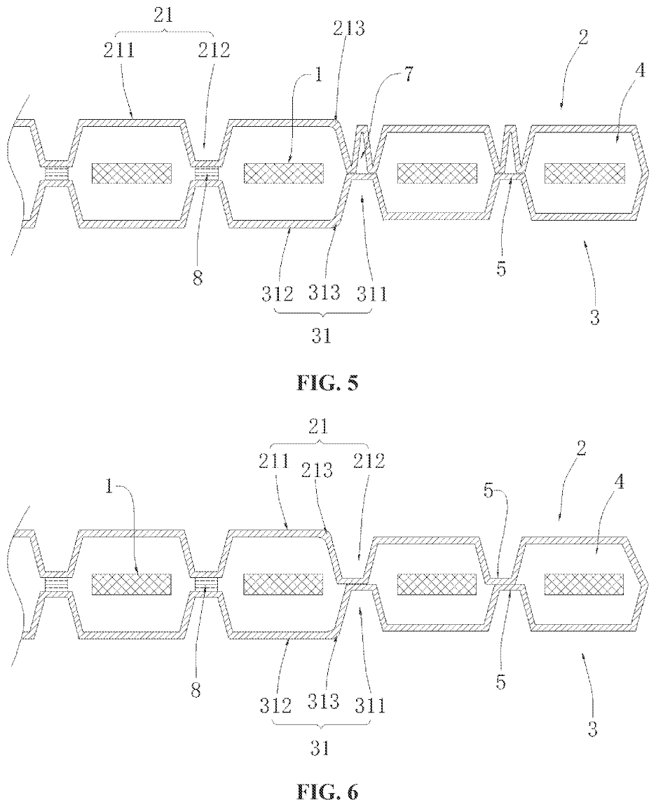

Specifically, as shown in FIG. 3 and FIG. 4, in some embodiments, one or more bumps 6 may be provided at the bottoms of outermost and 2^{nd} outermost the first troughs 212 of the first corrugated conductive diaphragm 2, and/or, one or more bumps 6 may be provided at the tops of outermost and 2^{nd} outermost the second crests of the second corrugated conductive diaphragm 3. A length of the bumps 6 in the third direction is less than the length of the planes 5 at the bottom of the first troughs 212 and on the tops of the second crests 311. By having the bumps 6 in contact with the planes 5 at the top of the second crests 311, the bumps 6 in contact with the planes 5 at the bottom of the first trough 212, and planes 5 at the bottoms of other first troughs 212 and the planes 5 at the tops of other second crests 311 in contact with each other, the contact area at the bottom of the corrugated conductive diaphragms can be reduced, thereby preventing the first troughs 212 and the second crests 311 from sticking to each other without being able to be separated at high structure displacements. Preferably, in order to avoid the bumps 6 being bonded to the planes of the first troughs 212 or the second crests 311 and increasing the stress, in an example, the bumps 6 may be anti-stiction bumps.

Specifically, as shown in FIG. 5, in some other embodiments, one or more dimples 7 may also be provided on the outermost and 2^{nd} outermost of first troughs 212 of the first corrugated conductive diaphragm 2, and/or, one or more dimples 7 may also be provided on the outermost and 2^{nd} outermost of second crests 311 of the second corrugated conductive diaphragm 3. Further, a length of the dimples 7 in the third direction is less than the length of the planes 5 at the bottoms of the first troughs 212 or on the tops of the second crests 311. By having the regions of the bottom of the first troughs 212 except the dimples 7 in contact with the planes on the tops of corresponding second crests 311, the regions of the tops of the second crests 311 except the dimples 7 in contact with the planes at the bottoms of corresponding first troughs 212, or the regions of the bottoms of the first troughs 212 except the dimples 7 and the regions of the tops of corresponding second crests 311 except the dimples 7 in contact with each other, the contact area at the bottoms of the corrugated conductive diaphragms can be reduced, thereby preventing the first troughs 212 and the second crests 311 from sticking to each other without being able to be separated at high structure displacements.

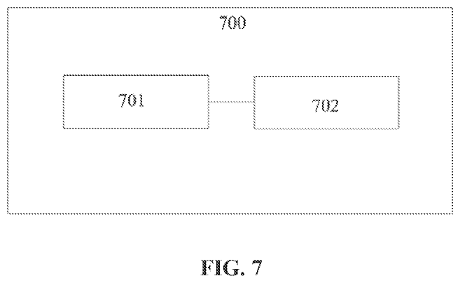

Specifically, as shown in FIG. 6, in another embodiment, the bottoms of the first troughs 212 and the tops of the second crests 311 are planes 5, in order to prevent the first troughs 212 and the second crests 311 from sticking to each other without being able to be separated at high structure displacements, the corrugations involved in the pressure engagement may be offset from each other by a certain portion of their length. That is, the bottoms of the first troughs 212 and/or the tops of the second crests 311 are configured to be offset a first distance in the third direction. Preferably, the first distance is less than the length of the planes 5. By misaligning the first troughs 212 and the second crests 311, the flat section in common and potentially reduce the risk of stiction can be reduced in a different way.

In other embodiments, the shape of the corrugation may be modified to achieve a similar function as the anti-stiction bumps. Herein, the base shape of one diaphragm (that is, shape of crest/trough) is intended to reduce the contact surface with the base of another diaphragm in the absence of spacers, a dome shape may be easily achieved when the bottom corrugation is implemented. Again, it may be a single dome shape or multiple dome shapes, and such shape can also be realized with the tops diaphragm.

As the high pressure gradient forces the two corrugations together, the two corrugations can effectively support each other at their respective bases (crest or trough). However, during the high non-linear bending exhibited in the shock and drop tests, the two corrugations can move freely in the second direction and slide in the first direction as well as in the third direction, which eliminates the need to conform one diaphragm shape to the other by using a portion of the device with such corrugated construction. As a result, the diaphragm eliminates an important element of additional bending, and stressed in this region can be reduced by up to 50%.

In some other embodiments, as shown in FIG. 7, an electro-acoustic conversion device 700 is provided, which includes the microelectromechanical system 701 described above and a driver circuit 702 electrically connected to the microelectromechanical system. The electro-acoustic conversion device 700 may be a microelectromechanical system microphone or speaker.

Although the present disclosure is described with reference to one or more embodiments, the above description of the embodiments is used only to enable people skilled in the art to practice or use the present disclosure. It should be appreciated by those skilled in the art that various modifications are possible without departing from the spirit or scope of the present disclosure. The embodiments illustrated above should not be interpreted as limits to the present disclosure, and the scope of the present disclosure is to be determined by reference to the claims that follow.

What is claimed is:

1. A microelectromechanical system comprising:
a plurality of counter electrodes, arranged in a first direction;
a first diaphragm and a second diaphragm respectively disposed at opposite sides of the plurality of counter electrodes along a second direction and hermetically connected;
wherein the first diaphragm is provided with a plurality of first corrugations, each of the plurality of first corrugations comprises a first crest and a first trough, and a plurality of first crests and a plurality of first troughs are arranged alternately in a third direction,
wherein the second diaphragm is provided with a plurality of second corrugation, each of the plurality of second corrugations comprises a second crest and a second trough, and a plurality of second crests and a plurality of second troughs are arranged alternately in the third direction;
wherein the plurality of first crests are respectively aligned with the plurality of second troughs to form cavities, and the plurality of counter electrodes are disposed in the cavities respectively; and
the plurality of first troughs are respectively aligned with the plurality of second crests, and at least some of the plurality of first troughs are configured to be in direct contact each other with corresponding second crests.

2. The microelectromechanical system according to claim 1, wherein the cavities are hermetically sealed, with an inside pressure less than an external atmosphere.

3. The microelectromechanical system according to claim 2, wherein the cavities are under vacuum.

4. The microelectromechanical system according to claim 1, wherein first troughs at outermost and 2^{nd} outermost rings of the first diaphragm are configured to be in direct contact each other with corresponding second crests at outermost and 2^{nd} outermost rings of the second diaphragm.

5. The microelectromechanical system according to claim 4, wherein bottoms of the first troughs and tops of the second crests are configured to be in a form of planes.

6. The microelectromechanical system according to claim 5, wherein a length of a region that a first trough and a corresponding second crest contacting with each other in the third direction is equal to or less than a length of the planes of the first trough and the corresponding second crest.

7. The microelectromechanical system according to claim 1, wherein the first diaphragm further comprises one or more bumps, the bumps being disposed at the bottoms of the first troughs and configured to be in contact with the tops of the second crests.

8. The microelectromechanical system according to claim 7, wherein a length of the bumps in the third direction is equal to or less than the length of the planes.

9. The microelectromechanical system according to claim 8, wherein the bumps form a circular shape or are in a form of a line.

10. The microelectromechanical system according to claim 1, wherein the second diaphragm further comprises one or more bumps, and the bumps being disposed at the tops of the second crests and configured to be in contact with the bottoms of the first troughs.

11. The microelectromechanical system according to claim 10, wherein a length of the bumps in the third direction are equal to or less than the length of the planes.

12. The microelectromechanical system according to claim 11, wherein the bumps are anti-stiction bumps or in a form of a line.

13. The microelectromechanical system according to claim 1, wherein the first diaphragm further comprises one or more dimples, the dimples being provided at the bottoms of the first troughs and configured to contact the tops of the second crests.

14. The microelectromechanical system according to claim 1, wherein the second diaphragm further comprises one or more dimples, the dimples being provided on the tops of the second crests, and regions of the second crests except the dimples being configured to contact the bottoms of the first troughs.

15. The microelectromechanical system according to claim 1, wherein the bottoms of the first troughs are configured to be offset a first distance from tops of corresponding second crests in the third direction.

16. The microelectromechanical system according to claim 15, wherein the first distance is less than the length of the planes.

17. The microelectromechanical system according to claim 15, wherein the third direction is a radial direction.

18. The microelectromechanical system according to claim 1, wherein tops of the first crests or bottoms of the second troughs are configured to be in a form of dome shapes.

19. The microelectromechanical system according to claim 18, wherein at least one bottom of the first crests or at least one top of the second troughs is configured to be in the form of the dome shapes.

20. An electro-acoustic conversion device comprising the microelectromechanical system according to claim 1, and a driver circuit electrically connected to the microelectromechanical system.
